(19) United States
(12) Patent Application Publication
(10) Pub. No.: US 2023/0386981 A1
(43) Pub. Date: Nov. 30, 2023

(54) SEMICONDUCTOR DEVICE

(71) Applicant: ROHM CO., LTD., KYOTO-SHI (JP)

(72) Inventor: Kengo OHMORI, Kyoto-shi (JP)

(73) Assignee: ROHM CO., LTD., KYOTO-SHI (JP)

(21) Appl. No.: 18/196,436

(22) Filed: May 12, 2023

(30) Foreign Application Priority Data
May 27, 2022 (JP) 2022-086950

(51) Int. Cl. H01L 23/495; H01L 23/00

(52) U.S. Cl. CPC H01L 23/4952; H01L 23/49562; H01L 23/49582; H01L 24/32; H01L 2224/32245; H01L 2924/13064

(57) ABSTRACT

A semiconductor device includes a switching element including an element obverse surface, leads, bonding layers, and a sealing resin. The switching element includes a first electrode, a second electrode, and a third electrode each formed at the element obverse surface. The leads include a first lead, a second lead, and a third lead. The bonding layers include a first bonding layer bonding the first lead and the first electrode, a second bonding layer bonding the second lead and the second electrode, and a third bonding layer bonding the third lead and the third electrode. The sealing resin includes a resin first surface facing in the same direction as the element obverse surface. The first lead, the second lead and the third lead include a first terminal portion, a second terminal portion and a third terminal portion, respectively, which are exposed at the resin first surface.

### CROSS-REFERENCE TO RELATED APPLICATION

The application claims priority to Japanese Patent Application No. 2022-086950, filed on May 27, 2022, the entire disclosure of which is hereby incorporated by reference in its entirety.

### FIELD

The present disclosure relates to a semiconductor device.

### BACKGROUND

Semiconductor devices with a semiconductor element such as a MOSFET (Metal Oxide Semiconductor Field Effect Transistor) or an IGBT (Insulated Gate Bipolar Transistor) are conventionally known. JP-A-2017-201675 discloses a conventional semiconductor device. The semiconductor device disclosed in the above patent document includes a plurality of leads, a semiconductor element, and a plurality of wires. The plurality of leads support and are electrically connected to the semiconductor element. The semiconductor element is a transistor. The semiconductor element is mounted on one of the leads. Each of the wires is bonded to the semiconductor element and one of the leads. With such a configuration, the semiconductor element is electrically connected to one of the leads with a wire.

### SUMMARY

During the switching of a semiconductor element, a surge voltage may be generated. When the generated surge voltage exceeds the withstand voltage of the semiconductor 35 element, the semiconductor element may be deteriorated and damaged. Because a larger internal inductance of the semiconductor device can lead to generation of a larger surge voltage, reducing the internal inductance of a semiconductor device is desirable for reducing a surge voltage. The semiconductor device described in the above-mentioned patent document still has room for improvement in reducing the internal inductance.

The present disclosure is conceived in light of the above circumstances and aims to provide a semiconductor device configured to reduce the internal inductance.

A semiconductor device provided according to the present disclosure includes: a switching element including an element obverse surface facing one side in a thickness direction; a plurality of leads spaced apart from each other and each facing the element obverse surface in the thickness direction; a plurality of bonding layers each interposed between the switching element and one of the plurality of leads; and a sealing resin covering the switching element and each of the plurality of bonding layers while exposing a part of each of the plurality of leads. The switching element has a first electrode, a second electrode, and a third electrode each formed at the element obverse surface. The plurality of leads include a first lead electrically connected to the first electrode, a second lead electrically connected to the second electrode, and a third lead electrically connected to the third electrode. The plurality of bonding layers include at least one first bonding layer that bonds the first lead and the first electrode to each other, at least one second bonding layer that bonds the second lead and the second electrode to each other, and at least one third bonding layer that bonds the third lead and the third electrode to each other. The sealing resin has a resin first surface facing in a same direction as the element obverse surface. The first lead includes a first terminal portion exposed at the resin first surface. The second lead includes a second terminal portion exposed at the resin first surface. The third lead includes a third terminal portion exposed at the resin first surface.

The semiconductor device according to the present disclosure can reduce the internal inductance.

### DRAWINGS

FIG. 1 is a plan view showing a semiconductor device according to a first embodiment;

FIG. 2 is a plan view corresponding to FIG. 1, in which a sealing resin is illustrated as transparent;

FIG. 3 is a plan view corresponding to FIG. 2, in which a semiconductor element is illustrated as transparent;

FIG. 4 is a bottom view of the semiconductor device according to the first embodiment;

FIG. 5 is a front view of the semiconductor device according to the first embodiment;

FIG. 6 is a rear view of the semiconductor device according to the first embodiment;

FIG. 7 is a sectional view taken along line VII-VII in

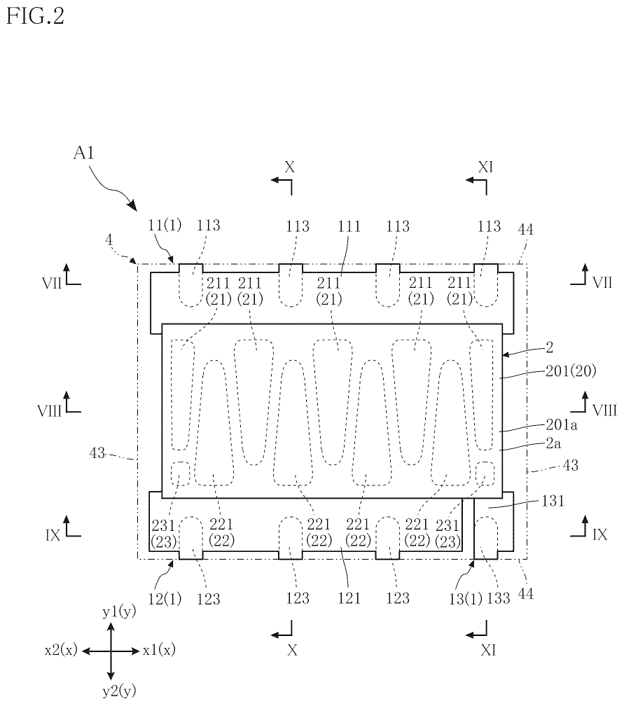

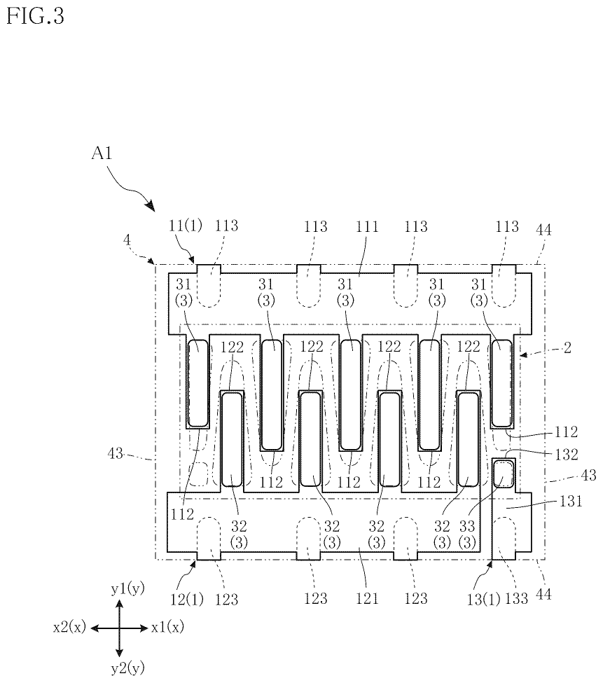

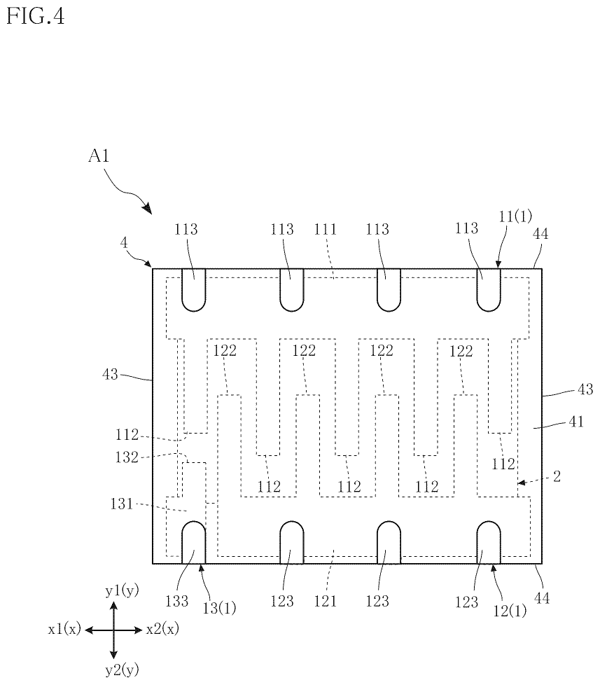

FIG. 2;

FIG. 8 is a sectional view taken along line VIII-VIII in FIG. 2;

FIG. 9 is a sectional view taken along line IX-IX in FIG. 2;

FIG. 10 is a sectional view taken along line X-X in FIG. 2;

FIG. 11 is a sectional view taken along line XI-XI in FIG. 2;

FIG. 12 is a plan view showing a semiconductor device according to a second embodiment;

FIG. 13 is a sectional view taken along the same plane as FIG. 8, showing the semiconductor device according to the second embodiment;

FIG. 14 is a sectional view taken along the same plane as FIG. 8, showing a semiconductor device according to a first variation of the second embodiment;

FIG. 15 is a plan view showing a semiconductor device according to a second variation of the second embodiment;

FIG. 16 is a sectional view taken along the same plane as FIG. 8, showing the semiconductor device according to the second variation of the second embodiment;

FIG. 17 is a sectional view taken along the same plane as FIG. 8, showing a semiconductor device according to a third variation of the second embodiment;

FIG. 18 is a plan view showing a semiconductor device according to a third embodiment, in which a sealing resin is illustrated as transparent;

FIG. 19 is a bottom view of the semiconductor device according to the third embodiment;

FIG. 20 is a sectional view taken along line XX-XX in FIG. 18, which can be compared to the view of FIG. 10; and

FIG. 21 is a sectional view taken along line XXI-XXI in FIG. 18, which can be compared to the view of FIG. 11.

### EMBODIMENTS

Preferred embodiments of the present disclosure are described below with reference to the accompanying drawings. In the description given below, the same or similar elements are denoted by the same reference signs, and the descriptions thereof are omitted. In the present disclosure, the terms “first”, “second”, “third” etc. are used merely as labels and are not necessarily intended to impose orders on the items to which these terms refer.

In the present disclosure, the phrases “an object A is formed in an object B” and “an object A is formed on an object B” include, unless otherwise specified, “an object A is formed directly in/on the object B” and “an object A is formed in/on the object B with another object interposed between the object A and the object B”. Similarly, the phrases “an object A is disposed in an object B” and “an object A is disposed on an object B” include, unless otherwise specified, “an object A is disposed directly in/on the object B” and “an object A is disposed in/on the object B with another object interposed between the object A and the object B”. Similarly, the phrase “an object A is located on an object B” includes, unless otherwise specified, “an object A is located on an object B in contact with the object B” and “an object A is located an object B with another object interposed between the object A and the object B”. Also, the phrase “an object A overlaps with an object B as viewed in a certain direction” includes, unless otherwise specified, an object A overlaps with the entirety of an object B″ and “an object A overlaps with a portion of an object B”. Also, the phrase “an object A (or the material thereof) contains a material C” includes “an object A (or the material thereof) is made of a material C” and “an object A (or the material thereof) is mainly composed of a material C”.

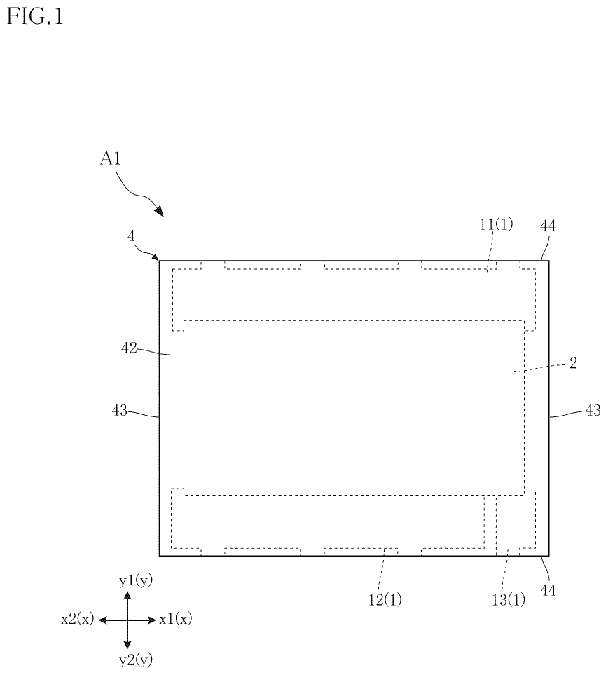

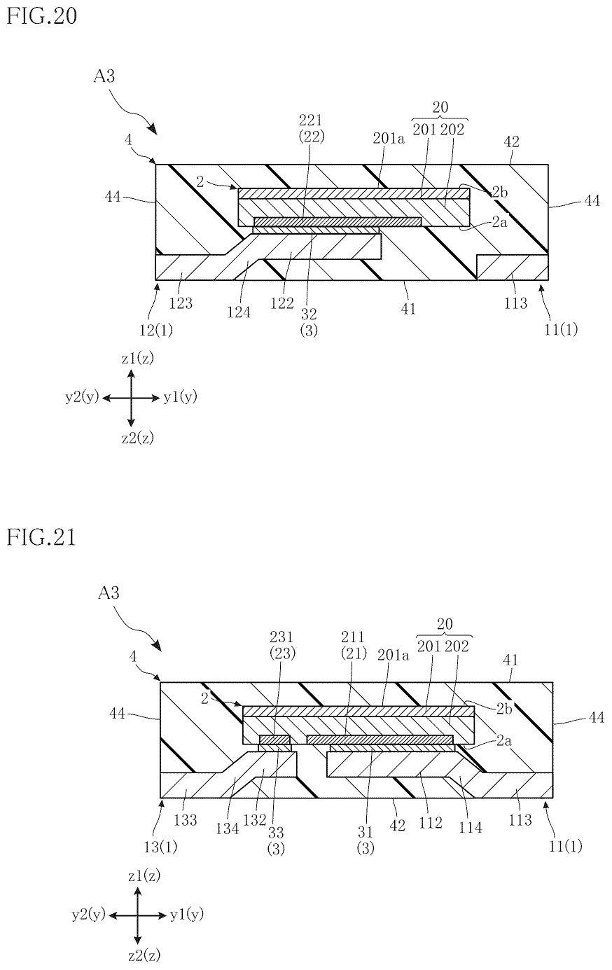

FIGS. 1 to 11 show a semiconductor device A1 according to a first embodiment. The semiconductor device A1 includes a plurality of leads 1, a switching element 2, a plurality of bonding layers 3, and a sealing resin 4. The semiconductor device A1 is an electronic component of a surface-mount type. In the illustrated example, the semiconductor device A1 has a package structure of a non-leaded type (e.g., DFN: “Dual Flatpack No-leaded” type), and none of the leads 1 project from the sealing resin 4 in plan view. Unlike this example, the semiconductor device may have a package structure in which the leads 1 project in a gull-wing manner (e.g., SOP: “Small Outline Package” type) or other package structures such as a BGA (Ball Grid Array) or an LGA (Land Grid Array. The semiconductor device of the present disclosure may have any package structure as long as the variation is technically compatible.

For convenience of explanation, the thickness direction of the semiconductor device A1 is referred to as “thickness direction z”. In the description below, one side in the thickness direction z may be referred to as “z1 side”, and the other side as “z2 side”. Also, one side or sense in the thickness direction z may be referred to as “upward” or “upper”, and the other side or sense as “downward” or “lower”. Note that the terms such as “top”, “bottom”, “upward”, “downward”, “upper surface”, and “lower surface” are used to indicate the relative position between parts, etc., in the thickness direction z and do not necessarily define the relationship with respect to the direction of gravity. Also, “plan view” refers to the view seen in the thickness direction z. A direction orthogonal to the thickness direction z is referred to as “first direction x”. The direction orthogonal to the thickness direction z and the first direction x is referred to as “second direction y”. In the description below, one side in the first direction x may be referred to as “x1 side”, and the other side as “x2 side”. Also, one side in the second direction y may be referred to as “y1 side”, and the other side as “y2 side”.

As shown in FIGS. 1 to 11, the plurality of leads 1 support the switching element 2 and form the terminals for mounting the semiconductor device A1 to a circuit board of an electronic device, for example. As shown in FIGS. 1 to 11, a part of each of the leads 1 is covered with the sealing resin 4. The leads 1 are located on the z2 side of the switching element 2 in the thickness direction z. The plurality of leads 1 are made of a single lead frame. The lead frame contains copper (Cu) or a copper alloy, for example. Each of the leads 1 has a thickness (dimension in the thickness direction z) of not less than 0.15 mm and not more than 0.25 mm. The thickness herein refers to the dimension of a part of each lead 1 that is largest in the thickness direction z (i.e., first terminal portions 113, second terminal portions 123, and a third terminal portion 133 described later). The plurality of leads 1 include a first lead 11, a second lead 12, and a third lead 13.

As shown in FIGS. 3, 4, 7, 8, 10 and 11, the first lead 11 includes a first base 111, a plurality of first strips 112, and a plurality of first terminal portions 113.

As shown in FIG. 3, the first base 111 is in the form of a rectangle elongated in the first direction x in plan view. As shown in FIGS. 2 and 3, in plan view, the first base 111 projects from the switching element 2 toward the y1 side in the second direction y while partially overlapping with the switching element 2. The first base 111 is covered with the sealing resin 4.

Each of the first strips 112 extends from the first base 111 toward the y2 side in the second direction y. Each first strip 112 is elongated in the second direction y in plan view. The first strips 112 are disposed side by side in a mutually spaced manner in the first direction x. The outermost one of the plurality of first strips 112 on each side in the first direction x is smaller in dimension in the second direction y than other first strips 112. Each of the first strips 112 overlaps with the switching element 2 in plan view. As shown in FIGS. 8 and 11, each first strip 112 is covered with the sealing resin 4.

Each of the first terminal portions 113 is thicker than the first base 111 and projects toward the z2 side in the thickness direction z relative to the first base 111. In the illustrated example, a part of each first terminal portion 113 projects from the first base 111 toward the y1 side in the second direction y in plan view. A part of each first terminal portion 113 is exposed from the sealing resin 4. In the present embodiment, the first terminal portions 113 are exposed at the lower surface of the sealing resin 4 (the resin first surface 41 described later) and the side surface of the sealing resin 4 on the y1 side in the second direction y (a first one of a pair of resin fourth surfaces 44 described later).

As shown in FIGS. 3, 4 and 8 to 10, the second lead 12 includes a second base 121, a plurality of second strips 122, and a plurality of second terminal portions 123.

As shown in FIG. 3, the second base 121 is in the form of a rectangle elongated in the first direction x in plan view. As shown in FIGS. 2 and 3, in plan view, the second base 121 projects from the switching element 2 toward the y2 side in the second direction y while partially overlapping with the switching element 2. The second base 121 is covered with the sealing resin 4.

Each of the second strips 122 extends from the second base 121 toward the y1 side in the second direction y. Each second strip 122 is elongated in the second direction y in plan view. The second strips 122 are disposed side by side in a mutually spaced manner in the first direction x. As shown in FIG. 3, the first strips 112 and the second strips 122 are alternately disposed in the first direction x. Each of the second strips 122 overlaps with the switching element 2 in plan view. As shown in FIGS. 8 and 10, each of the second strips 122 is covered with the sealing resin 4.

Each of the second terminal portions 123 is thicker than the second base 121 and projects toward the z2 side in the thickness direction z relative to the second base 121. In the illustrated example, a part of each second terminal portion 123 projects from the second base 121 toward the y2 side in the second direction y in plan view. A part of each second terminal portion 123 is exposed from the sealing resin 4. In the present embodiment, the second terminal portions 123 are exposed at the lower surface of the sealing resin 4 (the resin first surface 41 described later) and the side surface of the sealing resin 4 on the y2 side in the second direction y (a second one of the pair of resin fourth surfaces 44 described later).

The third lead 13 is located on the x1 side of the second lead 12 in the first direction x. As shown in FIGS. 3, 4, 9 and 11, the third lead 13 includes a third base 131, a third strip 132, and a third terminal portion 133.

As shown in FIG. 3, the third base 131 is rectangular. As shown in FIGS. 2 and 3, in plan view, the third base 131 projects from the switching element 2 toward the y2 side in the second direction y while partially overlapping with the switching element 2. The third base 131 is covered with the sealing resin 4.

The third strip 132 extends from the third base 131 toward the y1 side in the second direction y. The third strip 132 overlaps with the switching element 2 in plan view. As shown in FIG. 11, the third strip 132 is covered with the sealing resin 4. The third strip 132 is located on the y2 side in the second direction y of the outermost first strip 112 on the x1 side in the first direction x.

The third terminal portion 133 is thicker than the third base 131 and projects toward the z2 side in the thickness direction z relative to the third base 131. In the illustrated example, a part of the third terminal portion 133 projects from the third base 131 toward the y2 side in the second direction y in plan view. The third terminal portion 133 is exposed from the sealing resin 4. In the present embodiment, the third terminal portion 133 is exposed at the lower surface of the sealing resin 4 (the resin first surface 41 described later) and the side surface of the sealing resin 4 on the y2 side in the second direction y (the second one of the pair of resin fourth surfaces 44 described later).

The switching element 2 performs the electrical function of the semiconductor device A1. The switching element 2 contains nitride semiconductor, i.e., it is made using a nitride semiconductor material. The nitride semiconductor may be gallium nitride (GaN). Unlike this example, the switching element 2 may contain other semiconductor materials such as silicon (Si) or silicon carbide (SiC). In the present embodiment, the switching element 2 is a HEMT (High Electron Mobility Transistor). Unlike this example, the switching element 2 may be other transistors such as a MOSFET or an IGBT. The switching element 2 may be rectangular in in plan view. The switching element 2 may have a thickness (dimension in the thickness direction z) of not less than 50 μm and not more than 350 μm, for example. The withstand voltage of the switching element 2 is not limited, but may be 200 V or less, for example.

The switching element 2 has an element obverse surface 2a and an element reverse surface 2b. As shown in FIGS. 8, and 11, the element obverse surface 2a and the element reverse surface 2b face away from each other in the thickness direction z. In the present embodiment, the element obverse surface 2a faces downward (z2 side) in the thickness direction z so as to be opposed to the plurality of leads (the first lead 11, the second lead 12 and the third lead 13). The element reverse surface 2b faces upward (z1 side) in the thickness direction z.

As shown in FIGS. 8, 10 and 11, the switching element 2 includes an element body 20, a first electrode 21, a second electrode 22, and a third electrode 23.

The element body 20 forms the main part of the switching element 2. As shown in FIGS. 8, 10 and 11, the element body 20 has a substrate 201 and a semiconductor layer 202.

The substrate 201 supports the semiconductor layer 202, the first electrode 21, the second electrode 22, and the third electrode 23 on the z2 side in the thickness direction z. The substrate 201 contains a semiconductor material. The semiconductor material may be silicon (Si) or silicon carbide (SiC), for example. As shown in FIGS. 8, 10 and 11, the substrate 201 has a base surface 201a. The base surface 201a faces upward (z1 side) in the thickness direction z. In the semiconductor device A1, the base surface 201a forms the element reverse surface 2b. In the semiconductor device A1, the base surface 201a is covered with the sealing resin 4.

The semiconductor layer 202 is located on one side of the substrate 201 that is opposed to the leads 1 in the thickness direction z. In other words, the semiconductor layer 202 is on the surface of the substrate 201 that is opposite from the base surface 201a in the thickness direction z. The semiconductor layer 202 is a part of the element body 20 that is formed by laminating a buffer layer and a nitride layer (both not shown). The semiconductor layer 202 may contain various kinds of p-type semiconductors and n-type semiconductors which differ in amount of doped elements. The switching function of the switching element 2 as a HEMT is provided by the p-type semiconductors and the n-type semiconductors.

As shown in FIGS. 8, 10 and 11, each of the first electrode 21, the second electrode 22, and the third electrode 23 is formed at the element obverse surface 2a. Thus, each of the first electrode 21, the second electrode 22, and the third electrode 23 is located on the side opposed to the leads 1 in the thickness direction z. Each of the first electrode 21, the second electrode 22, and the third electrode 23 is connected to the element body 20. In the semiconductor device A1, the first electrode 21 is a drain electrode, the second electrode 22 is a source electrode, and the third electrode 23 is a gate electrode, for example. Unlike this example, the first electrode 21 may be a source electrode, and the second electrode 22 may be a drain electrode.

As shown in FIGS. 2 and 8, the first electrode 21 includes a plurality of first pad portions 211. In the illustrated example, the first electrode 21 includes five first pad portions 211, but the number of first pad portions 211 is not limited. Each of the first pad portions 211 is elongated in the second direction y in plan view. In the illustrated example, each first pad portion 211 is tapered from the y1 side toward the y2 side in the second direction y in plan view. Unlike this example, each first pad portion 211 may be rectangular in plan view. The above-mentioned first strips 112 are provided to correspond to the first pad portions 211, respectively. That is, the number of first strips 112 is the same as the number of first pad portions 211. At least the extremity of each first strip 112 may be tapered from the y1 side toward the y2 side in the second direction y to correspond to the shape of each first pad portion 211.

As shown in FIGS. 2 and 8, the second electrode 22 includes a plurality of second pad portions 221. In the illustrated example, the second electrode 22 includes four second pad portions 221, but the number of second pad portions 221 is not limited. Each of the second pad portions 221 is spaced apart from the first pad portions 211.

Each second pad portion 221 is elongated in the second direction y in plan view. In the illustrated example, each second pad portion 221 is tapered from the y2 side toward the y1 side in the second direction y in plan view. Unlike this example, each second pad portion 222 may be rectangular in plan view. The above-mentioned second strips 122 are provided to correspond to the second pad portions 221, respectively. That is, the number of second strips 122 is the same as the number of second pad portions 221. At least the extremity of each second strip 122 may be tapered from the y2 side toward the y1 side in the second direction y to correspond to the shape of each second pad portion 221.

The first pad portions 211 and the second pad portions 221 are alternately disposed in the first direction x. In the illustrated example, the outermost pad portions on respective sides in the first direction x are first pad portions 211.

As shown in FIG. 2, the third electrode 23 includes two third pad portions 231. Unlike this example, the third electrode 23 may include a single third pad portion 231.

Each third pad portion 231 is rectangular in plan view. Each third pad portion 231 is spaced apart from the first pad portions 211 and the second pad portions 221. One of the third pad portions 231 is disposed at one of the four corners of the switching element 2 at which the edge on the y2 side in the second direction y and the edge on the x1 side in the first direction x intersect, and the other of the third pad portions 231 is disposed at another corner at which the edge on the y2 side in the second direction y and the edge on the x2 side in the first direction x intersect. Each third pad portion 231 is located on the y2 side in the second direction y of the outermost one of the first/second pad portion 211, 222 in the first direction x. (In the semiconductor device A1, the outermost pad portions are first pad portions 211.)

The bonding layers 3 bond the leads 1 and the switching element 2 to each other. Each of the bonding layers 3 may be made of a conductive bonding material. Each bonding layer 3 may be solder, for example. Each bonding layer 3 may be metal paste or sintered metal, rather than solder. The metal paste or sintered metal may contain silver (Ag), copper, or gold. Each bonding layer 3 has a thickness (dimension in the thickness direction z) of not less than 5 μm and not more than 50 μm. The plurality of bonding layers 3 include a plurality of first bonding layers 31, a plurality of second bonding layers 32, and a third bonding layer 33.

Each of the first bonding layers 31 bonds and electrically connects the first lead 11 and the first electrode 21 to each other. Thus, the first lead 11 is electrically connected to the first electrode 21 via the first bonding layers 31. Because the first electrode 21 is a drain electrode in the semiconductor device A1, the first terminal portions 113 of the first lead 11 are drain terminals. The first bonding layers 31 bond the first strips 112 and the first pad portions 211 to each other, respectively.

Each of the second bonding layers 32 bonds and electrically connects the second lead 12 and the second electrode 22 to each other. Thus, the second lead 12 is electrically connected to the second electrode 22 via the second bonding layers 32. Because the second electrode 22 is a source electrode in the semiconductor device A1, the second terminal portions 123 of the second lead 12 are source terminals. The second bonding layers 32 bond the second strips 122 and the second pad portions 221 to each other, respectively.

The third bonding layer 33 bonds and electrically connects the third lead 13 and the third electrode 23 to each other. Thus, the third lead 13 is electrically connected to the third electrode 23 via the third bonding layer 33. Because the third electrode 23 is a gate electrode in the semiconductor device A1, the third terminal portion 133 of the third lead 13 is a gate terminal. The third bonding layer 33 bonds the third strip 132 and one of the two third pad portions 231 (the third pad portion 231 on the x1 side in the illustrated semiconductor device A1) to each other.

The sealing resin 4 covers a part of each of the leads 1, the switching element 2, and the bonding layers 3. The sealing resin 4 may include an insulating resin material. The insulating resin material may be epoxy resin, for example. The sealing resin 4 may be rectangular in in plan view. The sealing resin 4 may be formed by molding, for example. Prior to the molding, a part of the sealing resin 4 may be formed between the switching element 2 and the leads 1 by using an underfill material.

As shown in FIGS. 1 to 11, the sealing resin 4 has a resin first surface 41, a resin second surface 42, a pair of resin third surface 43, and a pair of resin fourth surfaces 44.

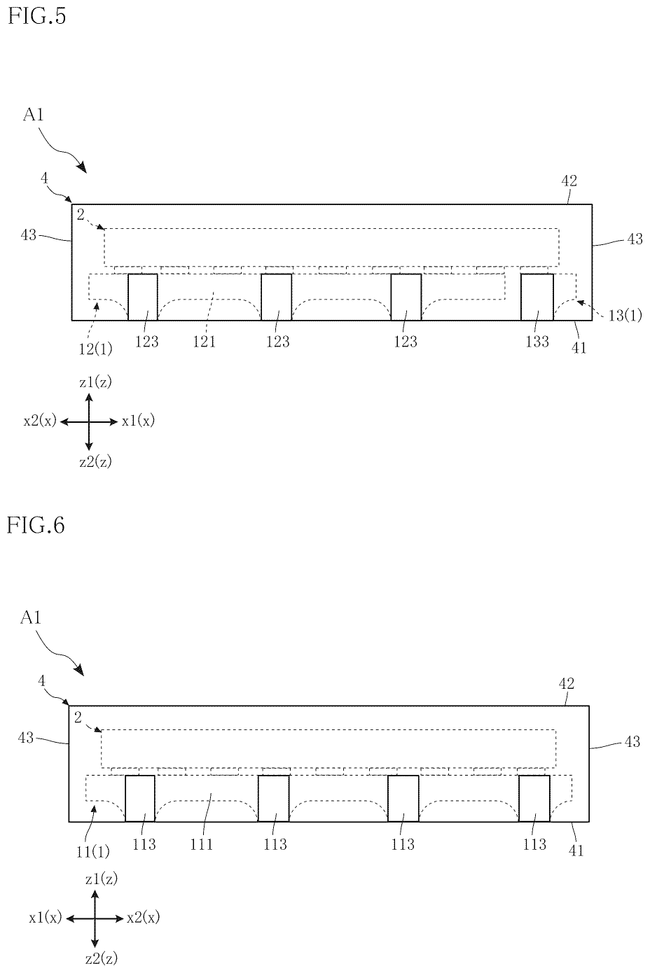

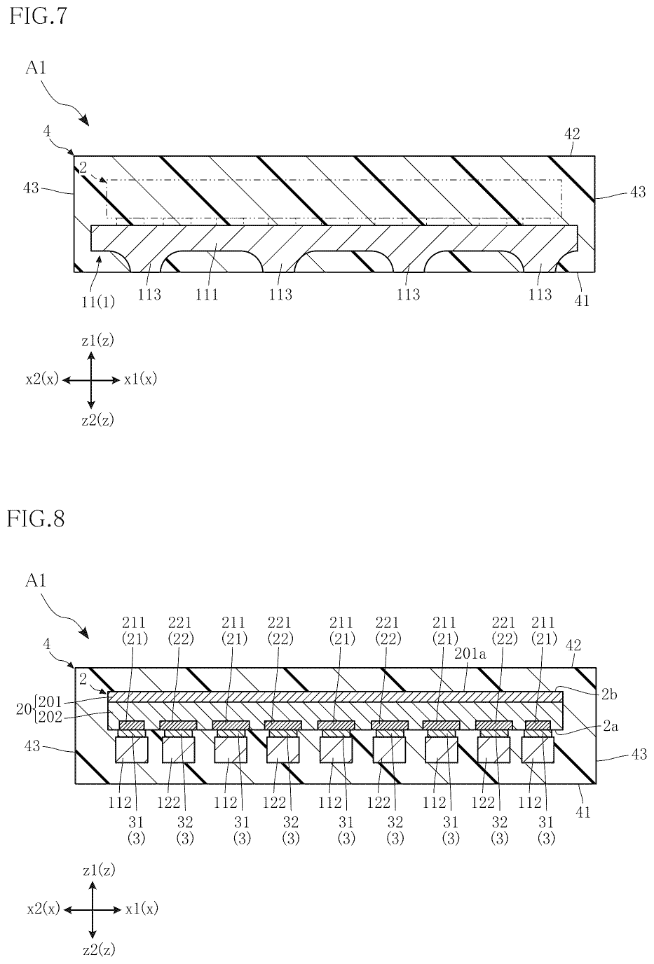

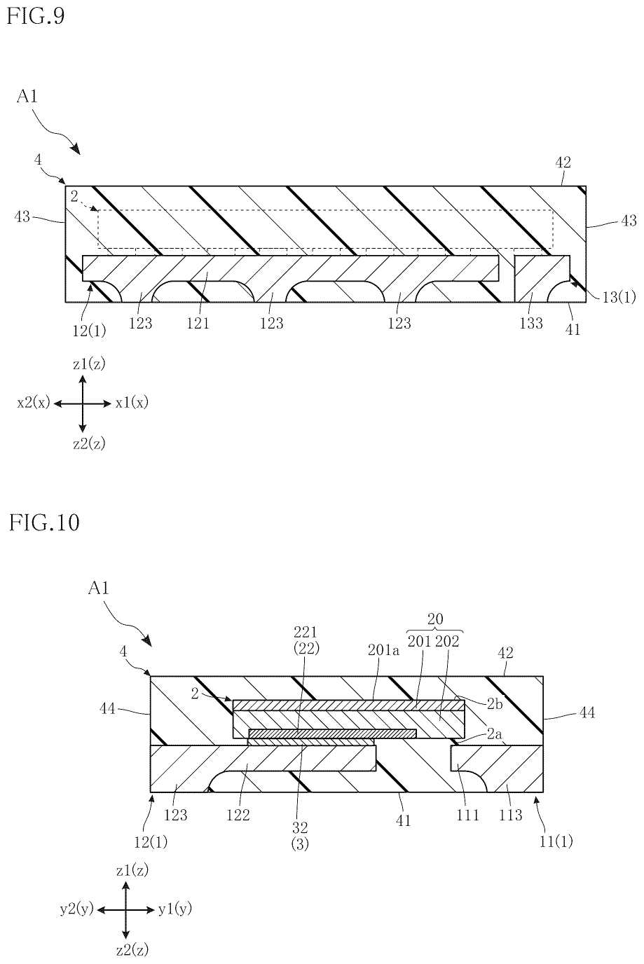

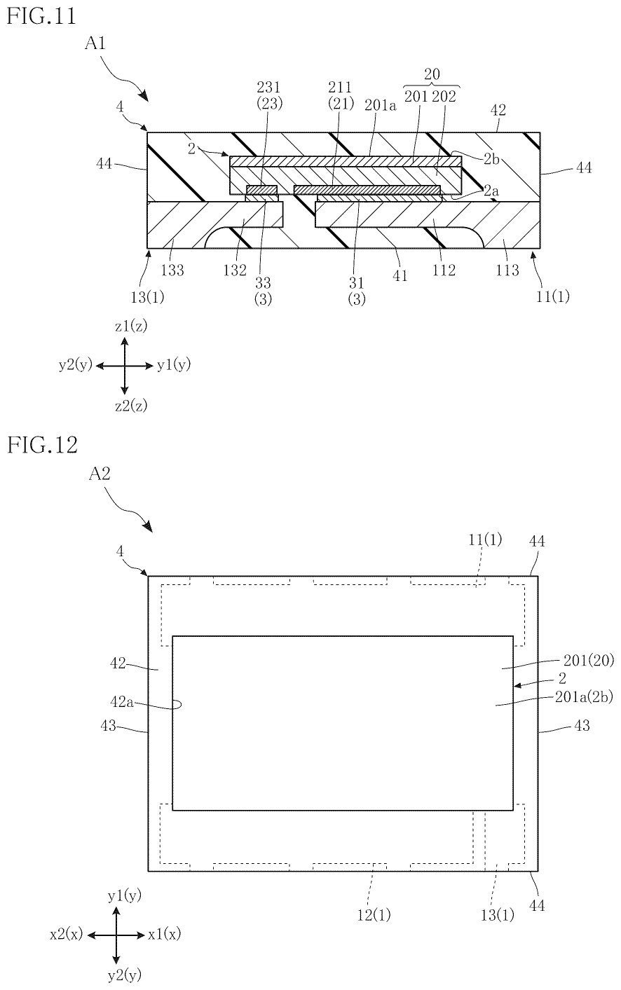

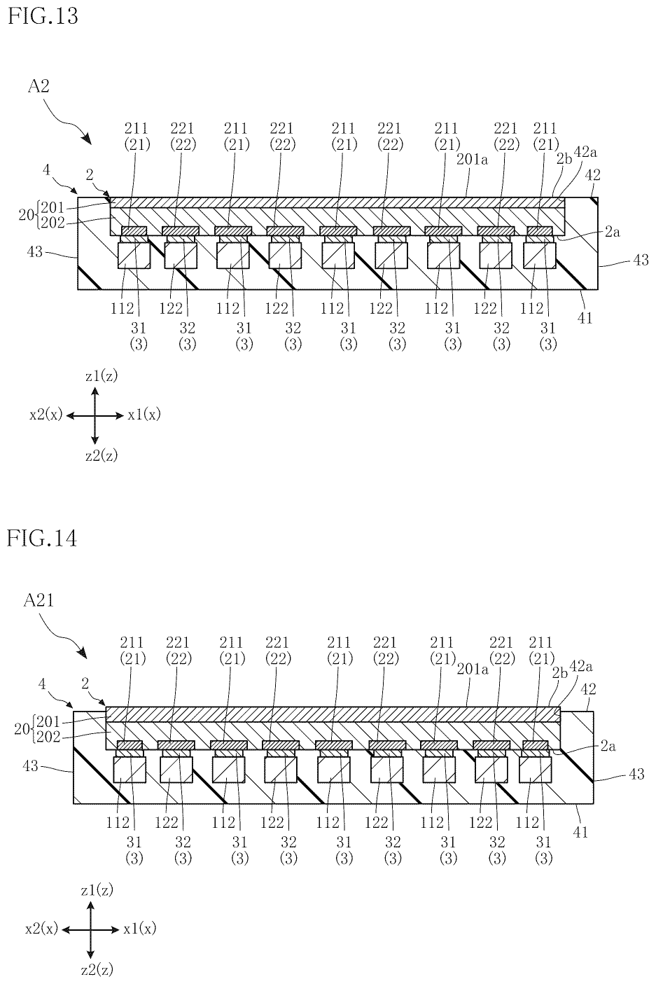

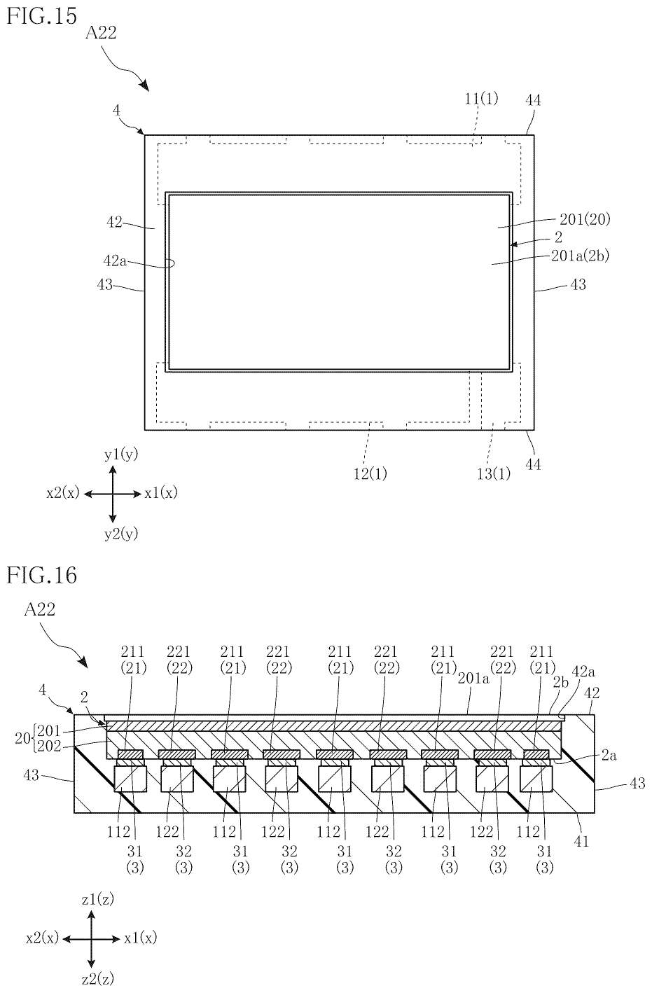

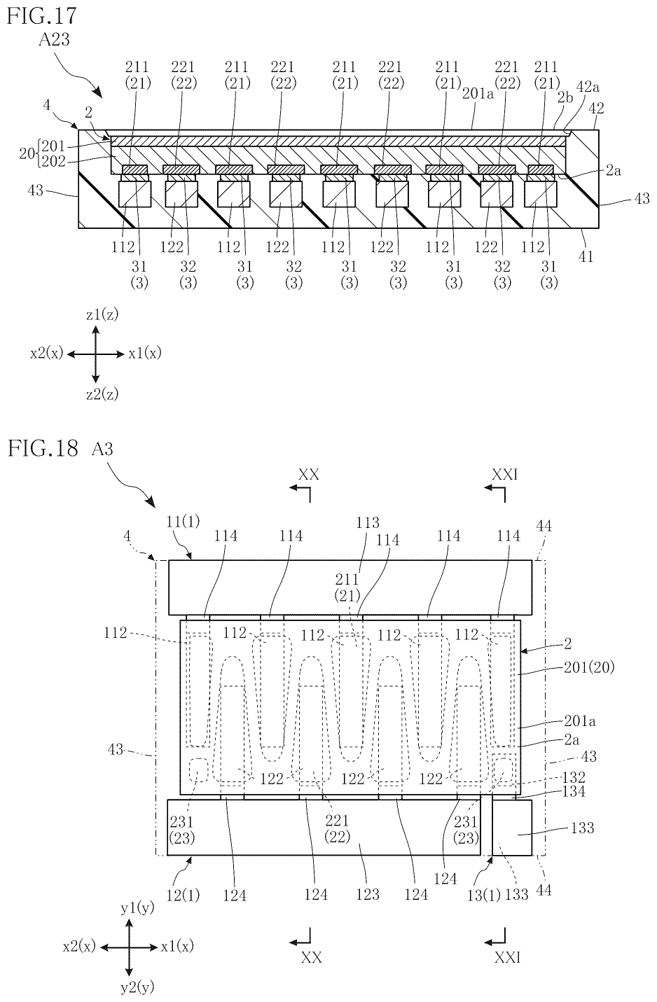

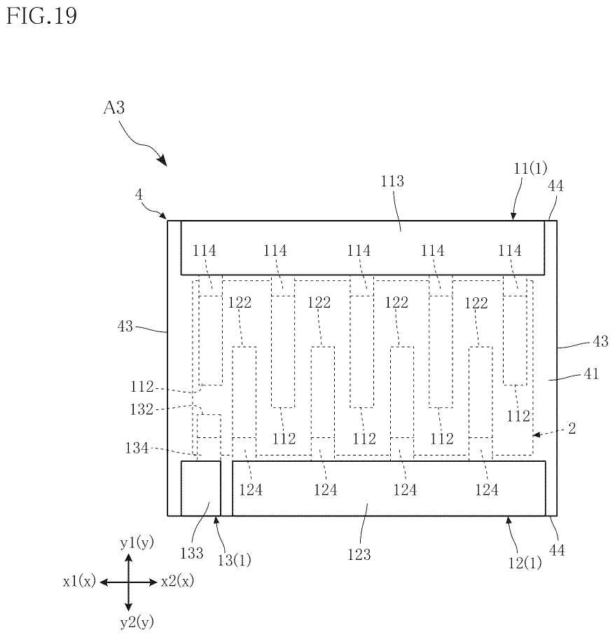

As shown in FIGS. 5 and 6, the resin first surface 41 and the resin second surface 42 are spaced apart from each other in the thickness direction z and face away from each other in the thickness direction z. As shown in FIGS. 10 and 11, the resin first surface 41 faces in the same direction as the element obverse surface 2a, and the resin second surface 42 faces in the same direction as the element reverse surface 2b. As shown in FIG. 4, the first terminal portions 113, the second terminal portions 123, and the third terminal portion 133 are exposed at the resin first surface 41.

The pair of resin third surfaces 43 and the pair of resin fourth surfaces 44 are flanked by the resin first surface 41 and the resin second surface 42 in the thickness direction z and connected to the resin first surface 41 and the resin second surface 42. The resin third surfaces 43 and the resin fourth surfaces 44 are each flat. As shown in FIGS. 1 to 4 and 5 to 9, the resin third surfaces 43 are spaced apart from each other in the first direction x and face away from each other in the first direction x. As shown in FIGS. 1 to 4, 10 and 11, the resin fourth surfaces 44 are spaced apart from each other in the second direction y and face away from each other in the second direction y. As shown in FIG. 6, the first terminal portions 113 are exposed at one of the resin fourth surfaces 44 (the resin fourth surface 44 on the y1 side in the second direction y). As shown in FIG. 5, the second terminal portions 123 and the third terminal portion 133 are exposed at the other one of the resin fourth surfaces 44 (the resin fourth surface 44 on the y2 side in the second direction y).

The effects and advantages of the semiconductor device A1 are described below.

In the semiconductor device A1, the first lead 11 and the first electrode 21 are bonded to each other with the first bonding layer 31, the second lead 12 and the second electrode 22 with the second bonding layer 32, and the third lead 13 and the third electrode 23 with the third bonding layer 33. Such a configuration realizes electrical connection without the use of a bonding wire between the first lead 11 and the first electrode 21, between the second lead 12 and the second electrode 22, and between the third lead 13 and the third electrode 23. Thus, the semiconductor device A1 can reduce the internal inductance as compared with a conventional semiconductor device (such as the semiconductor device disclosed in the above-mentioned patent document).

In the semiconductor device A1, the switching element 2 contains nitride semiconductor (e.g., GaN). With such a configuration, the maximum rated voltage is low, and hence the resistance to surge voltage is low, as compared with a configuration in which the switching element 2 contains Si (i.e., the switching element 2 is a Si device). For the configuration in which the switching element 2 contains nitride semiconductor, reducing the internal inductance of the semiconductor device is highly effective in preventing the breakdown of the switching element 2. In the semiconductor device A1, the withstand voltage of the switching element 2 can be 200 V or less, for example.

In the semiconductor device A1, the first lead 11 includes a plurality of first strips 112. The first strips 112 and the first pad portions 211 can be bonded, respectively, in accordance with the configuration of the first electrode 21 (the configuration including the first pad portions 211) of the switching element 2. Also, the second lead 12 includes a plurality of second strips 122. The second strips 122 and the second pad portions 221 can be bonded, respectively, in accordance with the configuration of the second electrode 22 (the configuration including the second pad portions 221) of the switching element 2.

In the semiconductor device A1, each of the first strips 112 is covered with the sealing resin 4 on both sides in the thickness direction z. Such a configuration prevents the first lead 11 from falling out of the sealing resin 4. Also, in the semiconductor device A1, the first base 111 is covered with the sealing resin 4. This further prevents the first lead 11 from falling out of the sealing resin 4 in the semiconductor device A1.

In the semiconductor device A1, each of the second strips 122 is covered with the sealing resin 4 on both sides in the thickness direction z. Such a configuration prevents the second lead 12 from falling out of the sealing resin 4. Also, in the semiconductor device A1, the second base 121 is covered with the sealing resin 4. This further prevents the second lead 12 from falling out of the sealing resin 4 in the semiconductor device A1.

In the semiconductor device A1, the third strip 132 is covered with the sealing resin 4 on both sides in the thickness direction z. Such a configuration prevents the third lead 13 from falling out of the sealing resin 4. Also, in the semiconductor device A1, the third base 131 is covered with the sealing resin 4. This further prevents the third lead 13 from falling out of the sealing resin 4 in the semiconductor device A1.

Other embodiments and variations of the semiconductor device according to the present disclosure are described below. The configurations of various parts in these embodiments and variations can be combined in any way as long as the variation is technically compatible.

FIGS. 12 and 13 show a semiconductor device A2 according to a second embodiment. As shown in the figure, the semiconductor device A2 differs from the semiconductor device A1 in that the element body 20 of the switching element 2 is exposed from the sealing resin 4.

In the semiconductor device A2, the resin second surface 42 of the sealing resin 4 has an opening 42a. The element reverse surface 2b of the switching element 2 (i.e., the base surface 201a of the substrate 201) is exposed through the opening 42a. Thus, the element body 20 is exposed at the resin second surface 42 of the sealing resin 4. The element reverse surface 2b of the switching element 2 is flush with the resin second surface 42. That is, the base surface 201a of the substrate 201 is flush with the resin second surface 42.

FIG. 14 shows a semiconductor device A21 according to a first variation of the second embodiment. As shown in the figure, the semiconductor device A21 differs from the semiconductor device A2 in that a part of the switching element 2 projects toward the z1 side in the thickness direction z relative to the resin second surface 42 of the sealing resin 4.

In the semiconductor device A21, the element reverse surface 2b of the switching element 2 (i.e., the base surface 201a of the substrate 201) is farther from the resin first surface 41 than is the resin second surface 42 in the thickness direction z. That is, the element reverse surface 2b of the switching element 2 is offset from the resin second surface 42 of the sealing resin 4 toward the z1 side in the thickness direction z.

FIGS. 15 and 16 show a semiconductor device A22 according to a second embodiment. The semiconductor device A22 differs from the semiconductor device A21 in that the resin second surface 42 of the sealing resin 4 has an indentation, and the element reverse surface 2b of the switching element 2 is exposed through the indentation.

In the semiconductor device A22, the element reverse surface 2b of the switching element 2 (i.e., the base surface 201a of the substrate 201) is closer to the resin first surface 41 than is the resin second surface 42. That is, the element reverse surface 2b of the switching element 2 is offset from the resin second surface 42 of the sealing resin 4 toward the z2 side in the thickness direction z. In the semiconductor device A22, the opening 42a is larger than the switching element 2 in plan view, as shown in FIG. 15. Unlike this example, the opening 42a may have the same size as the switching element 2 or may be smaller than the switching element 2, in plan view.

FIG. 17 shows a semiconductor device A23 according to a third variation of the second embodiment. The semiconductor device A23 differs from the semiconductor device A22 in that the wall surface defining the opening 42a is inclined with respect to the thickness direction z.

In the semiconductor device A23, because the surface defining the opening 42a is inclined, the area of the opening 42a in cross section orthogonal to the thickness direction z becomes larger from the z2 side toward the z1 side in the thickness direction z.

In the semiconductor devices A2, A21, A22 and A23, as with the semiconductor device A1, the first lead 11 and the first electrode 21 are bonded to each other with the first bonding layer 31, the second lead 12 and the second electrode 22 with the second bonding layer 32, and the third lead 13 and the third electrode 23 with the third bonding layer 33. Thus, as with the semiconductor device A1, the semiconductor devices A2, A21, A22 and A23 can reduce the internal inductance as compared with a conventional semiconductor device (such as the semiconductor device disclosed in the above-mentioned patent document).

In the semiconductor device A2, A21, A22 and A23, the element reverse surface 2b of the switching element 2 is exposed from the sealing resin 4. Such a configuration allows the heat generated during the energization of the switching element 2 to be dissipated from the element reverse surface 2b. Thus, the semiconductor device A2, A21, A22 and A23 improves heat dissipation as compared with the semiconductor device A1.

FIGS. 18 to 21 show a semiconductor device A3 according to a third embodiment. The semiconductor device A3 differs from the semiconductor device A1 in configuration of the leads 1.

The first lead 11 of the semiconductor device A3 includes a plurality of first strips 112, a first terminal portion 113, and a plurality of first connecting portions 114. The first terminal portion 113 is rectangular in plan view. As shown in FIG. 19, the lower surface (the surface facing the z2 side in the thickness direction z) of the first terminal portion 113 has the same size as the upper surface (the surface facing the z1 side in the thickness direction z), and is exposed at the resin first surface 41 of the sealing resin 4. The thickness (the dimension in the thickness direction z) of the first terminal portion 113 is the same as the thickness (the dimension in the thickness direction z) of each first strip 112. In the illustrated example, the first terminal portion 113 is located on the y1 side of the switching element 2 in the second direction y. As shown in FIG. 21, each of the first strips 112 is offset upward (toward the z1 side) in the thickness direction z from the first terminal portion 113. Each first strip 112 is covered with the sealing resin 4 on both sides in the thickness direction z. Each of the first connecting portions 114 connects the first terminal portion 113 and a relevant one of the first strips 112 to each other. As shown in FIG. 21, the first connecting portions 114 are inclined with respect to a plane (x-y plane) orthogonal to the thickness direction z. With such a configuration of the first connecting portions 114, the portions of the first lead 11 that connect the first terminal portion 113 and the first strips 112 to each other have a shape bent in the thickness direction z.

The second lead 12 of the semiconductor device A3 includes a plurality of second strips 122, a second terminal portion 123, and a plurality of second connecting portions 124. The second terminal portion 123 is rectangular in plan view. As shown in FIG. 19, the lower surface (the surface facing the z2 side in the thickness direction z) of the second terminal portion 123 has the same size as the upper surface (the surface facing the z1 side in the thickness direction z), and is exposed at the resin first surface 41 of the sealing resin 4. The thickness (the dimension in the thickness direction z) of the second terminal portion 123 is the same as the thickness (the dimension in the thickness direction z) of each second strip 122. In the illustrated example, the second terminal portion 123 is located on the y2 side of the switching element 2 in the second direction y. As shown in FIG. 20, each of the second strips 122 is offset upward (toward the z1 side) in the thickness direction z from the second terminal portion 123. As shown in FIG. 20, each second strip 122 is covered with the sealing resin 4 on both sides in the thickness direction z. Each of the second connecting portions 124 connects the second terminal portion 123 and a relevant one of the second strips 122 to each other. As shown in FIG. 20, the second connecting portions 124 are inclined with respect to the x-y plane. With such a configuration of the second connecting portions 124, the portions of the second lead 12 that connect the second terminal portion 123 and the second strips 122 to each other have a shape bent in the thickness direction z.

Similarly, the third lead 13 of the semiconductor device A3 includes a third strip 132, a third terminal portion 133, and a third connecting portion 134. The third terminal portion 133 is rectangular in plan view. As shown in FIG. 19, the lower surface (the surface facing the z2 side in the thickness direction z) of the third terminal portion 133 has the same size as the upper surface (the surface facing the z1 side in the thickness direction z), and is exposed from the resin first surface 41 of the sealing resin 4. The thickness (the dimension in the thickness direction z) of the third terminal portion 133 is the same as the thickness (the dimension in the thickness direction z) of the third strip 132. In the illustrated example, the third terminal portion 133 is located on the y2 side of the switching element 2 in the second direction y. As shown in FIG. 21, the third strip 132 is offset upward (toward the z1 side) in the thickness direction z from the third terminal portion 133. As shown in FIG. 21, the third strip 132 is covered with the sealing resin 4 on both sides in the thickness direction z. The third connecting portion 134 connects the third terminal portion 133 and the third strip 132 to each other. As shown in FIG. 21, the third connecting portion 134 is inclined with respect to the x-y plane. With such a configuration of the third connecting portion 134, the portion of the third lead 13 that connects the third terminal portion 133 and the third strip 132 to each other has a shape bent in the thickness direction z.

In the semiconductor devices A3, as with the semiconductor device A1, the first lead 11 and the first electrode 21 are bonded to each other with the first bonding layer 31, the second lead 12 and the second electrode 22 with the second bonding layer 32, and the third lead 13 and the third electrode 23 with the third bonding layer 33. Thus, as with the semiconductor device A1, the semiconductor device A3 can reduce the internal inductance as compared with a conventional semiconductor device (such as the semiconductor device disclosed in the above-mentioned patent document). In the semiconductor device A3, as with the semiconductor device A1, each first strip 112, each second strip 122 and the third strip 132 are covered with the sealing resin 4 on both sides in the thickness direction z. Thus, in the semiconductor device A3, the first lead 11, the second lead 12 and the third lead 13 are prevented from falling out of the sealing resin 4, as with the semiconductor device A1.

In the semiconductor device A3, the areas in plan view of the first terminal portion 113, the second terminal portion 123 and the third terminal portion 133 are larger as compared with those in the semiconductor device A1. With such a configuration, in mounting the semiconductor device A3 to a circuit board of e.g. an electronic device, reliable electrical connection with the circuit board is achieved. Also, because the semiconductor device A3 has an increased mounting area as compared with the semiconductor device A1, the bonding strength to the circuit board is improved.

Although the first through the third embodiments illustrate examples in which the switching element 2 is a transistor (e.g., HEMT), the present disclosure is not limited to this. The switching element 2 may be configured to include a switching circuit serving as a transistor and a control circuit that controls the switching circuit. The switching element 2 may be a composite element incorporating a control circuit. Alternatively, a control element (e.g., IC) containing the above-mentioned control circuit may be provided separately from the switching element 2. In such a variation, as with the switching element 2, the control element may be configured to be electrically connected to the leads by flip-chip bonding or to be electrically connected to the leads with bonding wires.

The semiconductor device according to the present disclosure is not limited to the foregoing embodiments. The specific configuration of each part of the semiconductor device according to the present disclosure may be varied in design in many ways. The semiconductor device of the present disclosure include the embodiments described in the following clauses.

Clause 1.

A semiconductor device comprising:

a switching element including an element obverse surface facing one side in a thickness direction;

a plurality of leads spaced apart from each other and each facing the element obverse surface in the thickness direction;

a plurality of bonding layers interposed between the switching element and the plurality of leads, respectively; and

a sealing resin covering the switching element and each of the plurality of bonding layers while exposing a part of each of the plurality of leads, wherein

the switching element includes a first electrode, a second electrode, and a third electrode each formed at the element obverse surface,

the plurality of leads include a first lead electrically connected to the first electrode, a second lead electrically connected to the second electrode, and a third lead electrically connected to the third electrode,

the plurality of bonding layers include at least one first bonding layer that bonds the first lead and the first electrode to each other, at least one second bonding layer that bonds the second lead and the second electrode to each other, and at least one third bonding layer that bonds the third lead and the third electrode to each other,

the sealing resin includes a resin first surface facing in a same direction as the element obverse surface,

the first lead includes a first terminal portion exposed at the resin first surface,

the second lead includes a second terminal portion exposed at the resin first surface, and

the third lead includes a third terminal portion exposed at the resin first surface.

Clause 2.

The semiconductor device according to clause 1, wherein the first electrode includes a plurality of first pad portions spaced apart from each other at the element obverse surface,

the second electrode includes a plurality of second pad portions spaced apart from each other at the element obverse surface, and

the plurality of first pad portions and the plurality of second pad portions are alternately disposed in a first direction orthogonal to the thickness direction.

Clause 3.

The semiconductor device according to clause 2, wherein each of the plurality of first pad portions and each of the plurality of second pad portions are in a form of a strip elongated in a second direction orthogonal to the thickness direction and the first direction, as viewed in the thickness direction.

Clause 4.

The semiconductor device according to clause 3, wherein the third electrode includes a third pad portion spaced apart from the plurality of first pad portions and the plurality of second pad portions at the element obverse surface, and

the third pad portion is located on one side in the second direction of an outermost one of the plurality of first pad portions and the plurality of second pad portions in the first direction.

Clause 5.

The semiconductor device according to clause 3 or 4, wherein the first lead includes a plurality of first strips elongated in the second direction as viewed in the thickness direction,

the at least one first bonding layer includes a plurality of first bonding layers, and

the plurality of first strips are bonded to the plurality of first pad portions with the plurality of first bonding layers, respectively.

Clause 6. The semiconductor device according to clause 5, wherein each of the first strips is covered with the sealing resin on both sides in the thickness direction.

Clause 7.

The semiconductor device according to clause 5 or 6, wherein the second lead includes a plurality of second strips elongated in the second direction as viewed in the thickness direction, the at least one second bonding layer includes a plurality of second bonding layers, and the plurality of second strips are bonded to the plurality of second pad portions with the plurality of second bonding layers, respectively.

Clause 8.

The semiconductor device according to clause 7, wherein each of the second strips is covered with the sealing resin on both sides in the thickness direction.

Clause 9.

The semiconductor device according to any one of clauses 1 to 8, wherein the switching element includes an element body,

the sealing resin includes a resin second surface opposite from the resin first surface in the thickness direction and an opening formed in the resin second surface, and the element body is exposed through the opening.

Clause 10.

The semiconductor device according to clause 9, wherein the element body includes a substrate and a semiconductor layer that is located closer to the element obverse surface than is the substrate and electrically connected to the first electrode, the second electrode and the third electrode,

the substrate includes a base surface facing in a same direction as the resin second surface, and the base surface is exposed through the opening.

Clause 11.

The semiconductor device according to clause 10, wherein the base surface is flush with the resin second surface.

Clause 12.

The semiconductor device according to clause 10, wherein the base surface is farther from the resin first surface than is the resin second surface in the thickness direction.

Clause 13.

The semiconductor device according to clause 10, wherein the base surface is closer to the resin first surface than is the resin second surface in the thickness direction.

Clause 14.

The semiconductor device according to any one of clauses 1 to 13, wherein the switching element contains nitride semiconductor.

Clause 15.

The semiconductor device according to any one of clauses 1 to 14, wherein the first electrode is a drain, the second electrode is a source, and

the third electrode is a gate.

Clause 16.

The semiconductor device according to any one of clauses 1 to 15, wherein the switching element has a withstand voltage of 200 V or less.

Clause 17.

The semiconductor device according to any one of clauses 1 to 16, wherein each of the plurality of bonding layers contains one of solder, Ag, Cu or Au.

1. A semiconductor device comprising:
a switching element including an element obverse surface facing one side in a thickness direction;
a plurality of leads spaced apart from each other and each facing the element obverse surface in the thickness direction;
a plurality of bonding layers interposed between the switching element and the plurality of leads, respectively; and
a sealing resin covering the switching element and each of the plurality of bonding layers while exposing a part of each of the plurality of leads, wherein
the switching element includes a first electrode, a second electrode, and a third electrode each formed at the element obverse surface,
the plurality of leads include a first lead electrically connected to the first electrode, a second lead electrically connected to the second electrode, and a third lead electrically connected to the third electrode,
the plurality of bonding layers include at least one first bonding layer that bonds the first lead and the first electrode to each other, at least one second bonding layer that bonds the second lead and the second electrode to each other, and at least one third bonding layer that bonds the third lead and the third electrode to each other,
the sealing resin includes a resin first surface facing in a same direction as the element obverse surface,
the first lead includes a first terminal portion exposed at the resin first surface,
the second lead includes a second terminal portion exposed at the resin first surface, and
the third lead includes a third terminal portion exposed at the resin first surface.

2. The semiconductor device according to claim 1, wherein the first electrode includes a plurality of first pad portions spaced apart from each other at the element obverse surface,
the second electrode includes a plurality of second pad portions spaced apart from each other at the element obverse surface, and
the plurality of first pad portions and the plurality of second pad portions are alternately disposed in a first direction orthogonal to the thickness direction.

3. The semiconductor device according to claim 2, wherein each of the plurality of first pad portions and each of the plurality of second pad portions are in a form of a strip elongated in a second direction orthogonal to the thickness direction and the first direction, as viewed in the thickness direction.

4. The semiconductor device according to claim 3, wherein the third electrode includes a third pad portion spaced apart from the plurality of first pad portions and the plurality of second pad portions at the element obverse surface, and
the third pad portion is located on one side in the second direction of an outermost one of the plurality of first pad portions and the plurality of second pad portions in the first direction.

5. The semiconductor device according to claim 3, wherein the first lead includes a plurality of first strips elongated in the second direction as viewed in the thickness direction,
the at least one first bonding layer includes a plurality of first bonding layers, and
the plurality of first strips are bonded to the plurality of first pad portions with the plurality of first bonding layers, respectively.

6. The semiconductor device according to claim 5, wherein each of the first strips is covered with the sealing resin on both sides in the thickness direction.

7. The semiconductor device according to claim 5, wherein the second lead includes a plurality of second strips elongated in the second direction as viewed in the thickness direction,
the at least one second bonding layer includes a plurality of second bonding layers, and
the plurality of second strips are bonded to the plurality of second pad portions with the plurality of second bonding layers, respectively.

8. The semiconductor device according to claim 7, wherein each of the second strips is covered with the sealing resin on both sides in the thickness direction.

9. The semiconductor device according to claim 1, wherein the switching element includes an element body,
the sealing resin includes a resin second surface opposite from the resin first surface in the thickness direction and an opening formed in the resin second surface, and
the element body is exposed through the opening.

10. The semiconductor device according to claim 9, wherein the element body includes a substrate and a semiconductor layer that is located closer to the element obverse surface than is the substrate and electrically connected to the first electrode, the second electrode and the third electrode,
the substrate includes a base surface facing in a same direction as the resin second surface, and
the base surface is exposed through the opening.

11. The semiconductor device according to claim 10, wherein the base surface is flush with the resin second surface.

12. The semiconductor device according to claim 10, wherein the base surface is farther from the resin first surface than is the resin second surface in the thickness direction.

13. The semiconductor device according to claim 10, wherein the base surface is closer to the resin first surface than is the resin second surface in the thickness direction.

14. The semiconductor device according to claim 1, wherein the switching element contains nitride semiconductor.

15. The semiconductor device according to claim 1, wherein the first electrode is a drain,
the second electrode is a source, and
the third electrode is a gate.

16. The semiconductor device according to claim 1, wherein the switching element has a withstand voltage of 200 V or less.

17. The semiconductor device according to claim 1, wherein each of the plurality of bonding layers contains one of solder, Ag, Cu or Au.
